(19) United States
(12) Patent Application Publication
(10) Pub. No.: US 2024/0421172 A1
(43) Pub. Date: Dec. 19, 2024

(54) TWO-WAY OPTICAL SENSOR PACKAGE AND A METHOD FOR FORMING THE SAME

(71) Applicant: STATS ChipPAC Pte. Ltd., Singapore (SG)

(72) Inventors: BumRyul MAENG, Incheon (KR); MyungHo JUNG, gyeonggi-do (KR)

(21) Appl. No.: 18/746,062

(22) Filed: Jun. 18, 2024

(30) Foreign Application Priority Data
Jun. 19, 2023 (CN) 202310726995.9

(51) Int. Cl. H01L 27/146

(52) U.S. Cl. CPC H01L 27/14634; H01L 27/14618; H01L 27/14636; H01L 27/14687; H01L 27/1469

(57) ABSTRACT

An optical sensor package comprises: a base substrate having a window; a first optical sensor mounted on a front surface of the base substrate, with its light receiving surface facing towards and aligned with the window; a first light-pervious encapsulant mold covering the light receiving surface of the first optical sensor; a first encapsulant layer formed on the front surface of the base substrate, wherein the first encapsulant layer comprises interlayer connects passing therethrough; an interposer mounted on the first encapsulant layer and electrically coupled to the base substrate through the interlayer connects of the first encapsulant layer; a second optical sensor mounted on a front surface of the interposer, with its light receiving surface facing away from the interposer; a second light-pervious encapsulant mold covering the light receiving surface of the second optical sensor; and a second encapsulant layer formed on the front surface of the interposer.

### TECHNICAL FIELD

The present application generally relates to semiconductor technologies, and more particularly, to a two-way optical sensor package and a method for forming a two-way optical sensor package.

### BACKGROUND OF THE INVENTION

Recently, sensor development is accelerating due to the expansion of the automotive and wearable device markets. It is expected that more optical sensors could be integrated within a single package so that the overall sensor package can be more compact.

Therefore, a need exists for further improvement to optical sensor packages.

### SUMMARY OF THE INVENTION

An objective of the present application is to provide a two-way optical sensor package with a compact structure.

According to an aspect of the present application, an optical sensor package is disclosed. The optical sensor package comprises: a base substrate having a window that passes therethrough; a first optical sensor mounted on a front surface of the base substrate, with its light receiving surface facing towards and aligned with the window of the base substrate; a first light-pervious encapsulant mold covering the light receiving surface of the first optical sensor, wherein the first light-pervious encapsulant mold is filled in the window of the base substrate; a first encapsulant layer formed on the front surface of the base substrate and encapsulating the first optical sensor, wherein the first encapsulant layer comprises interlayer connects passing therethrough; an interposer mounted on the first encapsulant layer and electrically coupled to the base substrate through the interlayer connects of the first encapsulant layer; a second optical sensor mounted on a front surface of the interposer, with its light receiving surface facing away from the interposer; a second light-pervious encapsulant mold covering the light receiving surface of the second optical sensor; and a second encapsulant layer formed on the front surface of the interposer to encapsulate the second optical sensor.

According to another embodiment of the present application, a method for forming an optical sensor package is disclosed. The method comprises: providing a base substrate; forming a window through the base substrate; providing a first optical sensor having a light receiving surface covered by a first light-pervious encapsulant mold and a second optical sensor having a light receiving surface covered by a second light-pervious encapsulant mold; mounting the first optical sensor on a front surface of the base substrate with the first light-pervious encapsulant mold filled in the window of the base substrate; forming interlayer connects on the front surface of the base substrate; forming a first encapsulant layer on the front surface of the base substrate to encapsulate the first optical sensor and the interlayer connects, wherein the interlayer connects pass through the first encapsulant layer; mounting an interposer on the interlayer connects to electrically couple the interposer with the base substrate; mounting the second optical sensor on a front surface of the interposer, with its light receiving surface and the second light-pervious encapsulant mold facing away from the interposer; and forming a second encapsulant layer on a front surface of the interposer to encapsulate the second optical sensor.

According to a further embodiment of the present application, a method for forming an optical sensor package is disclosed. The method comprises: providing a base substrate; forming a window through the base substrate; providing a first optical sensor having a light receiving surface covered by a first light-pervious encapsulant mold and a second optical sensor having a light receiving surface covered by a second light-pervious encapsulant mold; mounting the first optical sensor on a front surface of the base substrate with the first light-pervious encapsulant mold filled in the window of the base substrate; forming interlayer connects on the front surface of the base substrate; forming a first encapsulant layer on the front surface of the base substrate to encapsulate the first optical sensor and the interlayer connects, wherein the interlayer connects pass through the first encapsulant layer; providing an interposer; mounting the second optical sensor on a front surface of the interposer, with its light receiving surface and the second light-pervious encapsulant mold facing away from the interposer; forming a second encapsulant layer on a front surface of the interposer to encapsulate the second optical sensor; and attaching the interposer onto the first encapsulant layer to electrically couple the interposer with the base substrate through the interlayer connects.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a two-way optical sensor package according to an embodiment of the present application.

FIGS. 2A to 2D illustrate a method for forming an optical sensor assembly according to an embodiment of the present application.

FIGS. 3A to 3G illustrate a method for forming an optical sensor package according to an embodiment of the present application.

FIGS. 4A to 4B illustrate a method for forming an optical sensor package according to an embodiment of the present application.

FIGS. 5A to 5F illustrate a method for forming a sensor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

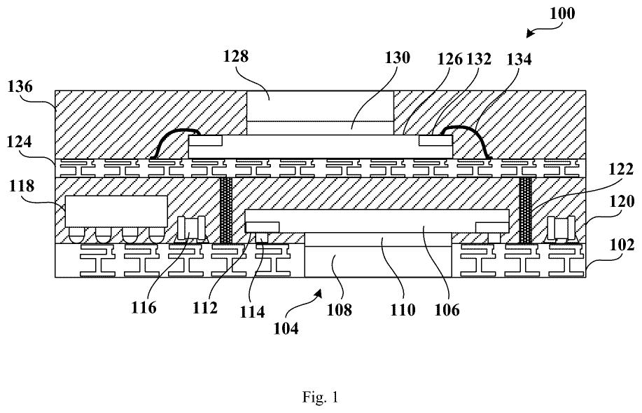

FIG. 1 illustrates a two-way optical sensor package 100 according to an embodiment of the present application. The optical sensor package 100 includes two optical sensors that face away from each other, to receive lights from both a front side and a back side of the package 100.

As shown in FIG. 1, the optical sensor package 100 includes a base substrate 102, which can provide support and connectivity for electronic components mounted thereon. By way of example, the base substrate 102 can include a printed circuit board (PCB), a carrier substrate, a semiconductor substrate with electrical interconnections, or a ceramic substrate. In some other examples, the base substrate 102 may include a laminate interposer, a strip interposer, a leadframe, or other suitable substrates. In some embodiments, the base substrate 102 may include a plurality of interconnection structures that can provide connectivity for electronic components mounted on the base substrate 102. The interconnection structures may include one or more of Cu, Al, Sn, Ni, Au, Ag, or any other suitable electrically conductive materials. In some examples, the interconnection structures may include redistribution structures. The redistribution structures may include one or more dielectric layers and one or more conductive layers between and through the dielectric layers. The conductive layers may define pads, traces and plugs through which electrical signals or voltages can be distributed horizontally and vertically across the redistribution structures.

The base substrate 102 has a front surface, and a back surface opposite to the front surface. A window 104 is formed in the base substrate 102 and passes through the base substrate 102 between its front surface and back surface. In some embodiments, conductive patterns such as contact pads and/or solder bumps may be formed on the back surface of the base substrate 102 to allow for connecting the optical sensor package 100 with an external electronic device or system such as a printed circuit board.

A first optical sensor assembly is mounted on the front surface of the base substrate 102. In particular, the first optical sensor assembly may include a first optical sensor 106 such as an image sensor die or an infrared sensor die, which has a light receiving surface for receiving lights emitted from a space where the optical sensor package 100 is positioned. Alternatively, the first optical sensor 106 can also incorporate one or more additional functions such as image signal processing function therein to improve the integration level of the optical sensor package 100. As shown in FIG. 1, the light receiving surface of the first optical sensor 106 is facing towards and aligned with the window 104 of the base substrate 102, such that it can receive lights emitted from the back side of the optical sensor package 100 through the window 104. The first optical sensor assembly also includes a light-pervious encapsulant mold 108 which covers the light receiving surface of the first optical sensor 106 but allows light transmission through the first light-pervious encapsulant mold 108. The first light-pervious encapsulant mold 108 is filled in the window 104. In this way, an overall height of the optical sensor package 100 can be reduced because there is some overlap in height between the base substrate 102 and the first optical sensor assembly. In some embodiments, a front surface of the first light-pervious encapsulant mold 108 may be substantially flush with the back surface of the base substrate 102 to form a flat plane at the back surface. The first light-pervious encapsulant mold 108 may be made of a light-pervious material such as glass, silicone, resin or other suitable materials or composition thereof, and may be formed using a molding process such as injection molding or compression molding. In some embodiments, an optical filter layer 110 may be formed between the first optical sensor 106 and the first light-pervious encapsulant mold 108 for light filtering.

Besides its light receiving surface, the first optical sensor 106 also has a set of conductive patterns 112 such as contact pads. The conductive patterns 112 can be electrically coupled to the base substrate 102 via a set of solder bumps 114 between the first optical sensor 106 and the base substrate 102. The solder bumps 114 can be for example stub bumps which can be preformed on the front surface of the first optical sensor 106 before it is mounted onto the base substrate 102. The set of conductive patterns 112 and the solder bumps 114 may be uniformly distributed around the light receiving surface and at a peripheral region of the first optical sensor 106, such that the first optical sensor 106 can be firmly bonded with the base substrate 102. In some embodiments, the first optical sensor assembly may be formed independently as a piece before it is mounted onto the base substrate 102. An exemplary process for forming the first optical sensor assembly and other similar optical sensor assemblies will be elaborated below.

In some embodiments, at least one electronic component such as one or more passive devices 116 (e.g., capacitors or resistors) and one or more semiconductor dice 118 may be attached onto the front surface of the base substrate 102. These electronic components can be electrically coupled to the first optical sensor 106 through the base substrate 102, to provide more functions for the optical sensor package 100. For example, the semiconductor die 118 may include an application specific integrated circuit (ASIC) that may provide additional signal or data processing capability, or may include a memory that may store images captured by the first optical sensor 106 or store other data generated by the circuit in the optical sensor package 100.

A first encapsulant layer 120 is formed on the front surface of the base substrate 102, which can encapsulate the first optical sensor 106, and optionally, the at least one electronic component mounted on the front surface of the base substrate 102. In some embodiments, the first encapsulant layer 120 may be made of a polymer composite material, such as epoxy resin with or without filler, epoxy acrylate with or without filler, or polymer with or without proper filler, but the scope of this application is not limited thereto. In addition, interlayer connects 122 such as metal posts may be formed on the base substrate 102. The interlayer connects 122 may pass through the first encapsulant layer 120 and thus provide interlayer connectivity. The interlayer connects 122 may be electrically connected to certain conductive patterns on the front surface of the base substrate 102. The number of the interlayer connects 122 may depend on the need for signal transmission in the optical sensor package 100.

An interposer 124 is mounted on the first encapsulant layer 120 and electrically coupled to the base substrate 102 through the interlayer connects 122. Similar as the base substrate 102, the interposer 102 may include a plurality of interconnection structures that can provide connectivity therethrough, and optionally, for electronic components mounted on the interposer 124. The interconnection structures may include one or more of Cu, Al, Sn, Ni, Au, Ag, or any other suitable electrically conductive materials. In some examples, the interconnection structures may include one or more conductive layers between and through the interposer 124. The conductive layers may define pads, traces and plugs through which electrical signals or voltages can be distributed horizontally and vertically across the interconnection structures, and through the interposer 124.

A second optical sensor assembly is mounted on a front surface of the interposer 124. In some embodiments, the second optical sensor assembly may be the same as the first optical sensor assembly, while in some other embodiments, the second optical sensor assembly may be different from the first optical sensor assembly. For example, the second optical sensor assembly may have a bigger size as there is more space for mounting it. In the embodiment shown in FIG. 1, the second optical sensor assembly has a structure similar as the first optical sensor assembly, for example, they may be preformed using the same process, or even in a same batch. In particular, the second optical sensor assembly may have a second optical sensor 126 with its light receiving surface facing away from the interposer 124. The second optical sensor 126 can receive lights emitted from the front side of the optical sensor package 100. In this way, the first optical sensor 106 and the second optical sensor 126 can implement two-way light detection with respect to the optical sensor package 100. The second optical sensor assembly also includes a second light-pervious encapsulant mold 128 which covers the light receiving surface of the second optical sensor 126 but allows light transmission. The second light-pervious encapsulant mold 128 may be made of a light-pervious material such as glass, silicone, resin or other suitable materials or composition thereof, and may be formed using a molding process such as injection molding or compression molding. In some embodiments, an optical filter layer 130 may be formed between the second optical sensor 126 and the second light-pervious encapsulant mold 128 for light filtering. Besides its light receiving surface, the second optical sensor 126 also has a set of conductive patterns 132 such as contact pads on its front surface. The conductive patterns 132 can be electrically coupled to the interposer 124 via a set of bonding wires 134.

Furthermore, a second encapsulant layer 134 is formed on the front surface of the interposer 124, which can encapsulate the second optical sensor 126 as well as the second light-pervious encapsulant mold 128. However, a front surface of the second light-pervious encapsulant mold 128 can be exposed from the second encapsulant layer 134 to avoid the second encapsulant layer 134 from blocking light transmission. The second encapsulant layer 134 may be formed of a material the same as or different from the material of the first encapsulant layer 120. In some embodiments, the second encapsulant layer 134 may be formed along with the first encapsulant layer 120, while in some other embodiments, the first and second encapsulant layers 120 and 134 may be formed separately.

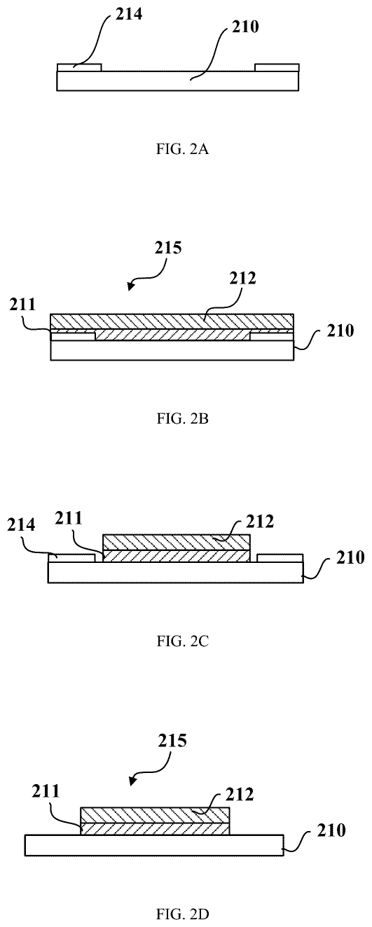

FIGS. 2A to 2D illustrate a method for forming an optical sensor assembly according to an embodiment of the present application. For example, the method can be used to form the first optical sensor assembly and/or the second optical sensor assembly of the optical sensor package 100 shown in FIG. 1.

As shown in FIG. 2A, an optical sensor 210 is provided. It can be appreciated that the optical sensor 210 may not be an individual sensor chip that has already been singulated from a sensor wafer. Rather, the optical sensor 210 may be an unsingulated optical sensor of a sensor wafer, with other identical or similar optical sensors in the sensor wafer as well. Although not shown in FIG. 2A, certain conductive patterns (not shown) may be formed on a front surface of the optical sensor 210 to provide for electrical connectivity of the optical sensor 210 with other electronic components.

A patterned photoresist layer 214 may be formed on the optical sensor 210, or particularly on a front surface of the optical sensor 210. The patterned photoresist layer 214 at least partially covers a conductive pattern of the sensor 210 but exposes a light receiving surface or area of the optical sensor 210. In particular, a photoresist layer fully covering the front surface of the optical sensor 210 may be formed on top of the front surface of the optical sensor 210, for example, using printing, spin coating, or spray coating. Then the photoresist layer can be formed with certain patterns using such as a lithography process.

Next, as shown in FIG. 2B, an optical filter layer 211 and a light-pervious encapsulant layer 212 are formed on the optical sensor 210. In particular, the optical filter layer 211 is formed on top of the front surface of the optical sensor 210. The optical filter layer 211 covers and is in direct contact with the light receiving surface of the optical sensor 210 and the patterned photoresist layer. Preferably, the optical filter layer 211 fully covers the exposed portion of the light receiving surface and the patterned photoresist layer. Afterwards, the light-pervious encapsulant layer 212 is formed on top of the optical filter layer 211. Preferably, the light-pervious encapsulant layer 212 may entirely cover the entire optical filter layer 211.

Further referring to FIG. 2C, a portion of the light-pervious encapsulant layer 212 and a portion of the optical filter layer 211 are removed, so as to expose the patterned photoresist layer 214. In some embodiments, the removal may adopt a half-cut process performed with a saw or a laser cutting tool. The position where the half-cut process is performed is selected such that the patterned photoresist layer 214 is at least partially exposed after the half-cut process. A depth of the half-cut process may be equal to or larger than a total thickness of the light-pervious encapsulant layer 212 and the optical filter layer 211, yet smaller than the total thickness of the light-pervious encapsulant layer 212, the optical filter layer 211 and the patterned photoresist layer 214. In some embodiments where the depth of the half-cut process is smaller than the total thickness of the light-pervious encapsulant layer 212, the optical filter layer 211 and the patterned photoresist layer 214, some patterned photoresist layer 214 may remain on the optical sensor 210. In other words, the patterned photoresist layer 214 may not be fully removed so that the remaining photoresist layer 214 can protect the conductive pattern thereunder from damage during the half-cut process. The remaining patterned photoresist layer 214 may be removed later with a photoresist stripping process such as organic stripping, inorganic stripping or dry stripping, as shown in FIG. 2D. As such, an optical sensor assembly 215 is formed. After the half cut process, the optical filter layer 211 and light-pervious encapsulant layer 212 can be patterned as an optical filter 211 and a light-pervious encapsulant mold 212, respectively.

It can be appreciated that if the optical sensor is manufactured with other similar sensors on the same wafer, a singulation process may be performed to separate these optical sensors from each other, which will not be elaborated herein.

Various processes may be used to manufacture the optical sensor package 100 shown in FIG. 1. Below some exemplary processed will be described, which can be subsequent to the steps for forming optical sensors shown in FIGS. 2A to 2D.

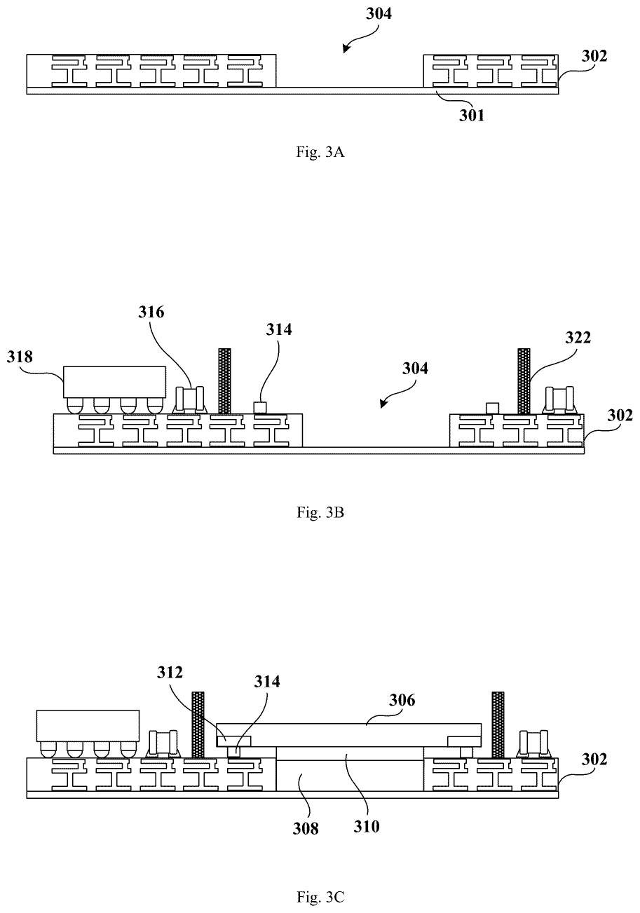

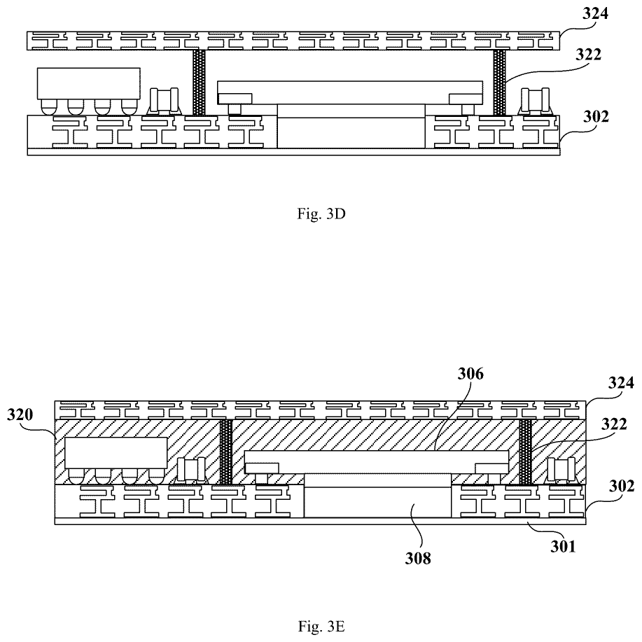

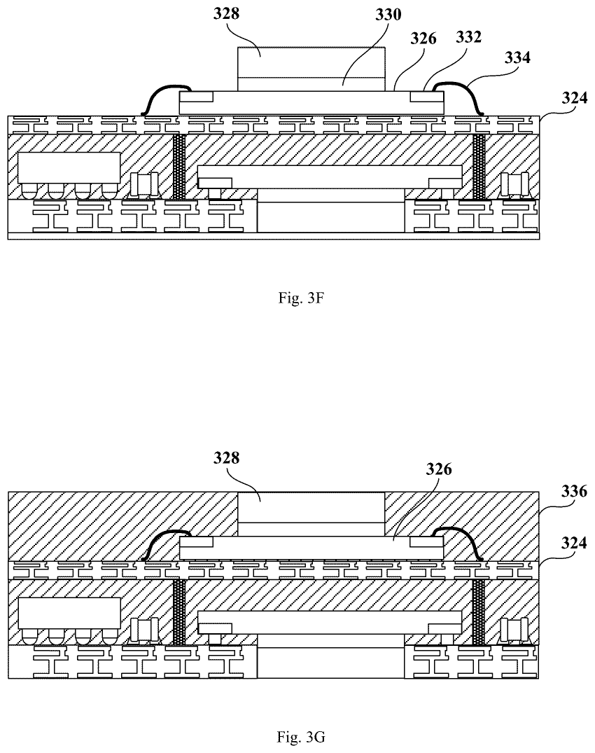

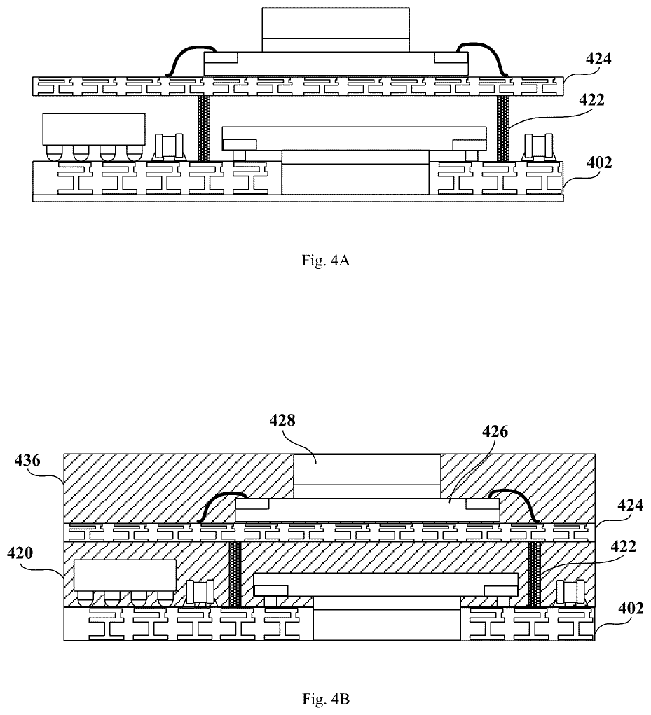

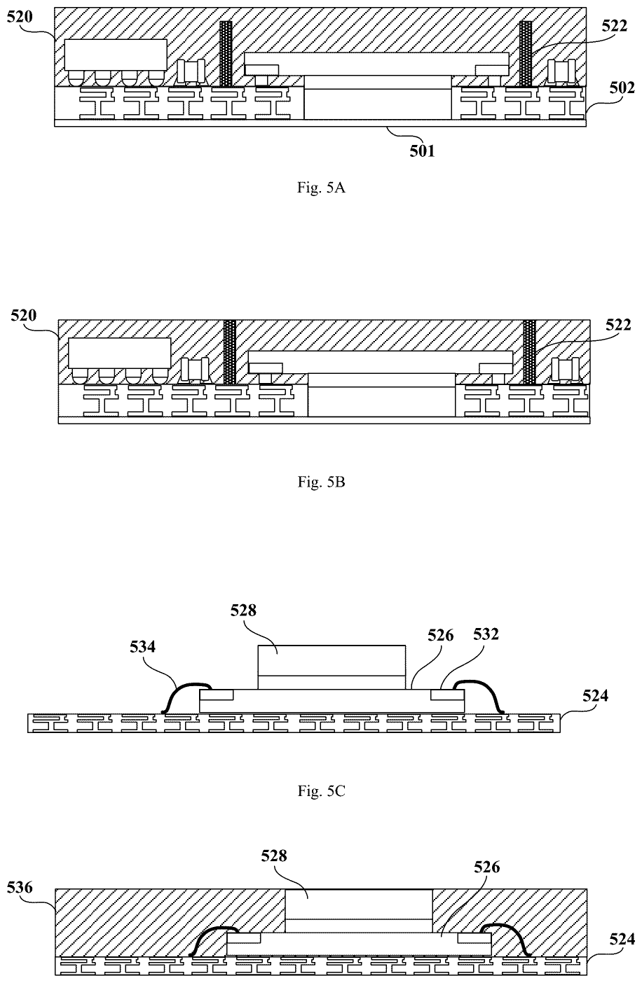

FIGS. 3A to 3G illustrate a method for forming an optical sensor package according to an embodiment of the present application.

As shown in FIG. 3A, a base substrate 302 is provided. The base substrate 302 may be mounted on a carrier 301 such as a carrier tape or a carrier platform that provides support for the base substrate 302 during subsequent steps. It can be appreciated that the base substrate 302 may be a substrate strip or plate having a plurality of unitary portions such as that shown in FIG. 3A, which can be singulated into individual units or pieces when the packaging process is completed or substantially completed. A window 304 can be formed through the base substrate 302, for example, using an etching process such as laser ablation. A shape of the window 304 may vary depending on an optical sensor assembly to be fitted in the window 304. In some embodiments, the window 304 may be of a circular shape, a rectangular shape or a square shape.

Next, as shown in FIG. 3B, various electronic components such as one or more passive devices 316 and one or more semiconductor dice 318 may be mounted on a front surface of the base substrate 302, and these electronic components may form a sensor module or system together with optical sensors which will later be mounted on the base substrate 302. Furthermore, some other components that may facilitate the mounting of the optical sensor assemblies of the optical sensor package may be mounted on the front surface of the base substrate 302. In particular, a set of solder bumps 314 such as stub bumps may be formed around the window 304. These solder bumps 314 may be formed on some of the conductive patterns on the front surface of the base substrate 302. Interlayer connects 322 such as metal posts can be formed on the front surface of the base substrate 302 as well. The interlayer connects 322 may have a height greater than the electronic components on the base substrate 302.

As shown in FIG. 3C, a first optical sensor assembly may be mounted on the front surface of the base substrate 302. The first optical sensor assembly includes a first optical sensor 306 with a light receiving surface, a first light-pervious encapsulant mold 308, and optionally an optical filter layer 310 between the first optical sensor 306 and the first light-pervious encapsulant mold 308. The first light-pervious encapsulant mold 308 and the optical filter layer 310 cover the light receiving surface of the first optical sensor 306. When the optical sensor assembly is mounted on the base substrate 302, the light receiving surface can face downward and be aligned with the window of the base substrate 302. Also, conductive patterns 312 such as contact pads on the front surface of the first optical sensor 306 can be aligned with the solder bumps 314, such that the first optical sensor assembly can be firmly attached on the base substrate 302, for example, after a solder reflow process. In some embodiments, an adhesive material, an encapsulant material or other suitable filler materials may be filled in a gap between the window and the first light-pervious encapsulant mold 308 to form tight seal therebetween.

Afterwards, as shown in FIG. 3D, an interposer 324 is mounted over the base substrate 302 and supported by the interlayer connects 322. The interposer 324 can therefore be electrically coupled to the base substrate 302 through the interlayer connects 322. As shown in FIG. 3E, a first encapsulant layer 320 can be formed on the front surface of the base substrate 302 to encapsulate the first optical sensor 306 and other components on the base substrate 302. The encapsulant material of the first encapsulant layer 320 can well occupy the space between the base substrate 302 and the interposer 324. In some embodiments, the encapsulant material of the first encapsulant layer 320 may fill in the gap between the window of the base substrate 302 and the first light-pervious encapsulant mold 308 to form tight seal therebetween. Due to the existence of the carrier 301, the encapsulant material may not flow onto the back surface of the base substrate 302. In some embodiments, the first encapsulant layer 302 may be formed using a molding process such as injection molding or compression molding.

Next, as shown in FIG. 3F, a second optical sensor assembly is mounted on a front surface of the interposer 324. The second optical sensor assembly includes a second optical sensor 326 with a light receiving surface that faces away from the interposer 324, a second light-pervious encapsulant mold 328, and optionally an optical filter layer 330 between the second optical sensor 326 and the second light-pervious encapsulant mold 328. The second light-pervious encapsulant mold 328 and the optical filter layer 330 cover the light receiving surface of the second optical sensor 326. In some embodiments, the second optical sensor assembly may be attached on the front surface of the interposer 324 through an adhesive material. Also, the second optical sensor 326 may have a set of conductive patterns 332 around its light receiving surface, which can be electrically coupled to the interposer 332 through respective bonding wires 334.

Lastly, as shown in FIG. 3G, a second encapsulant layer 336 may be formed on the front surface of the interposer 324 to encapsulate the second optical sensor assembly. It can be appreciated that a front surface of the second light-pervious encapsulant mold 328 can be exposed from the second encapsulant layer 336 such that light can pass through the second light-pervious encapsulant mold 328 onto the light receiving surface of the second optical sensor 326. Then the optical sensor package can be formed. As mentioned above, a singulation process may be formed to separate the package strip into individual packages, which can be further removed from the carrier.

FIGS. 4A and 4B illustrate a method for forming an optical sensor package according to another embodiment of the present application. Different from the encapsulation steps shown in FIGS. 3E to 3G that form the two encapsulant layers separately, a single encapsulation step is used in the embodiment shown in FIGS. 4A and 4B.

As shown in FIG. 4A, various components including two optical sensor assemblies are mounted on a base substrate 402 and an interposer 424, respectively, and the base substrate 402 and the interposer 424 are mechanically and electrically coupled with each other via interlayer connects 422 therebetween.

After that, an encapsulant molding process may be performed, as shown in FIG. 4B. A first encapsulant layer 420 may be formed between the base substrate 402 and the interposer 424, and encapsulate the interlayer connects 422 and other electronic components on the base substrate 402. Furthermore, a second encapsulant layer 436 may be formed on the interposer 424 to encapsulate the second optical sensor assembly but expose a front surface of a second light-pervious encapsulant mold 428 of the second optical sensor assembly. The second encapsulant layer 436 can well protect a second optical sensor 426 of the second optical sensor assembly. A benefit for the one-step encapsulation process is that thermal stress between different encapsulant layers can be reduced compared with the two-step encapsulation process such that shown in FIGS. 3A to 3G.

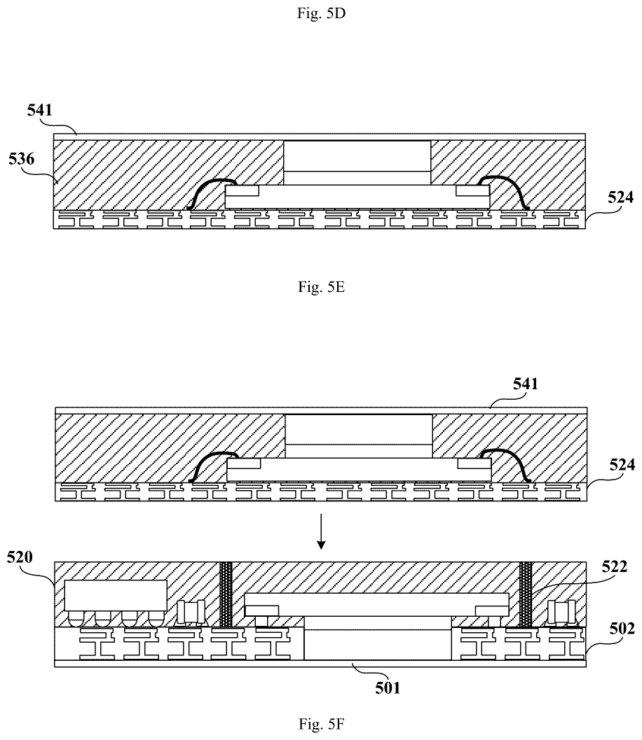

FIGS. 5A to 5F illustrate a method for forming an optical sensor package according to a further embodiment of the present application. Different from methods shown in FIGS. 3A to 3G and FIGS. 4A and 4B, the two layers of electronic components are separately mounted onto a base substrate and an interposer and then assembled together in the embodiment shown in FIGS. 5A to 5F.

As shown in FIG. 5A, a base substrate 502 may be attached onto a first carrier 501. Then a first optical sensor assembly may be mounted on the base substrate 502, with various other components including interlayer connects 522 such as metal posts. Afterwards, a first encapsulant layer 520 may be formed on a front surface of the base substrate 502, which may cover and encapsulate all the components on the base substrate 502. The first encapsulant layer 520 may have a height greater than that of the interlayer connects 522. Next, as shown in FIG. 5B, a grinding process may be performed to the first encapsulant layer 520 to remove an excessed portion of the first encapsulant layer 520. As such, top surfaces of the interlayer connects 522 can be exposed from the first encapsulant layer 520.

As shown in FIG. 5C, as a separate process, a second optical sensor assembly having a second optical sensor 526, a second light-pervious encapsulant mold 528, and optionally an optical filtering layer, may be mounted onto an interposer 524 through an adhesive material, for example. The second optical sensor 526 may have conductive patterns 532 on its front surface, which can be electrically coupled to the interposer 524 via a set of bonding wires 534. Next, as shown in FIG. 5D, a second encapsulant layer 536 may be formed on the interposer 524 to encapsulate the second optical sensor assembly but expose a front surface of the second light-pervious encapsulant mold 528. The second encapsulant layer 536 may be attached onto a second carrier 541 such as a carrier tape, with a back surface of the interposer 524 away from the second carrier 541, as shown in FIG. 5E.

Lastly, as shown in FIG. 5F, the two portions of the optical sensor package which are separately formed using the steps shown in FIG. 5A, and FIGS. 5B to 5D, can be attached with each other, using some adhesive materials. In particular, after the attaching process, the interlayer connects 522 can be electrically coupled to the interposer 524, such that the interposer 524 and the second optical sensor assembly mounted thereon can be electrically coupled to the base substrate 502 and the components mounted thereon through the interlayer connects 522. In some embodiments, an anisotropic conductive film may be used to attach the two portions of the optical sensor package because it can be electrically conductive in a vertical direction only at locations where the interlayer connects 522 are and can be non-conductive in a horizontal direction. As mentioned above, a singulation process may be formed to separate a package strip of multiple optical sensor packages into individual packages. Then the first carrier 501 and the second carrier 541 may be removed from the optical sensor package.

It can be appreciated that the two portions of the optical sensor package may be assembled with each other in other manners. For example, instead of the second carrier 541, a clamp, a vacuum cup or other suitable tools may be used to move the interposer 524 and the second optical sensor assembly thereon to the base substrate 502 and stack them onto the first encapsulant layer 520. Alternatively, the two portions of the optical sensor package may be removed from the first and second carriers respectively, and then be moved together using any other suitable tools or equipment.

It can be seen that the optical sensor packages according to the embodiments of the present application are compact in structure, and can avoid some components such as caps or lids which are required for conventional optical sensor packages. Furthermore, the two-layer structure of the optical sensor packages allows for detecting lights emitted from two sides of the package, i.e., a two-way direction can be implemented.

While the optical sensor package of the present application is described in conjunction with corresponding figures, it will be understood by those skilled in the art that modifications and adaptations to the semiconductor package may be made without departing from the scope of the present invention.

The discussion herein includes numerous illustrative figures that show various portions of an optical sensor package and a method for forming the optical sensor package. For illustrative clarity, such figures do not show all aspects of each example semiconductor package. Any of the example optical sensor packages provided herein may share any or all characteristics with any or all other optical sensor packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An optical sensor package, comprising:
a base substrate having a window that passes therethrough;
a first optical sensor mounted on a front surface of the base substrate, with its light receiving surface facing towards and aligned with the window of the base substrate;
a first light-pervious encapsulant mold covering the light receiving surface of the first optical sensor, wherein the first light-pervious encapsulant mold is filled in the window of the base substrate;
a first encapsulant layer formed on the front surface of the base substrate and encapsulating the first optical sensor, wherein the first encapsulant layer comprises interlayer connects passing therethrough;
an interposer mounted on the first encapsulant layer and electrically coupled to the base substrate through the interlayer connects of the first encapsulant layer;
a second optical sensor mounted on a front surface of the interposer, with its light receiving surface facing away from the interposer;
a second light-pervious encapsulant mold covering the light receiving surface of the second optical sensor; and
a second encapsulant layer formed on the front surface of the interposer to encapsulate the second optical sensor.

2. The optical sensor package of claim 1, further comprising:
at least one electronic component mounted on the front surface of the base substrate, wherein the at least one electronic component is electrically coupled to the first and second optical sensors.

3. The optical sensor package of claim 1, wherein the first optical sensor comprises a set of conductive patterns besides its light receiving surface, and the set of conductive patterns are electrically coupled to the base substrate via a set of solder bumps between the first optical sensor and the base substrate.

4. The optical sensor package of claim 1, wherein the first light-pervious encapsulant mold has a front surface that is substantially flush with a back surface of the base substrate.

5. The optical sensor package of claim 1, wherein the interlayer connects comprise metal posts.

6. The optical sensor package of claim 1, wherein the second optical sensor comprises a set of conductive patterns besides its light receiving surface, and the set of conductive patterns are electrically coupled to the interposer through a set of bonding wires.

7. A method for forming an optical sensor package, comprising:
providing a base substrate;
forming a window through the base substrate;
providing a first optical sensor having a light receiving surface covered by a first light-pervious encapsulant mold and a second optical sensor having a light receiving surface covered by a second light-pervious encapsulant mold;
mounting the first optical sensor on a front surface of the base substrate with the first light-pervious encapsulant mold filled in the window of the base substrate;
forming interlayer connects on the front surface of the base substrate;
forming a first encapsulant layer on the front surface of the base substrate to encapsulate the first optical sensor and the interlayer connects, wherein the interlayer connects pass through the first encapsulant layer;
mounting an interposer on the interlayer connects to electrically couple the interposer with the base substrate;
mounting the second optical sensor on a front surface of the interposer, with its light receiving surface and the second light-pervious encapsulant mold facing away from the interposer; and
forming a second encapsulant layer on the front surface of the interposer to encapsulate the second optical sensor.

8. The method of claim 7, wherein forming a window through the base substrate comprises:
attaching a back surface of the base substrate onto a carrier; and
etching the base substrate to form the window.

9. The method of claim 7, where before forming a first encapsulant layer on the front surface of the base substrate, the method further comprises:
mounting at least one electronic component on the front surface of the base substrate, wherein the at least one electronic component is electrically coupled to the first and second optical sensors.

10. The method of claim 7, wherein the first optical sensor comprises a set of conductive patterns besides its light receiving surface, and the set of conductive patterns are electrically coupled to the base substrate via a set of solder bumps between the first optical sensor and the base substrate.

11. The method of claim 7, wherein the first light-pervious encapsulant mold has a front surface that is substantially flush with a back surface of the base substrate.

12. The method of claim 7, wherein the interlayer connects comprise metal posts.

13. The method of claim 7, wherein the second optical sensor comprises a set of conductive patterns besides its light receiving surface, and the method further comprises:
forming a set of bonding wires on the front surface of the interposer to electrically couple the set of conductive patterns of the second optical sensor with the interposer.

14. The method of claim 7, wherein forming the first encapsulant layer and forming the second encapsulant layer are performed in a single encapsulation process.

15. A method for forming an optical sensor package, comprising:
providing a base substrate;
forming a window through the base substrate;
providing a first optical sensor having a light receiving surface covered by a first light-pervious encapsulant mold and a second optical sensor having a light receiving surface covered by a second light-pervious encapsulant mold;
mounting the first optical sensor on a front surface of the base substrate with the first light-pervious encapsulant mold filled in the window of the base substrate;
forming interlayer connects on the front surface of the base substrate;
forming a first encapsulant layer on the front surface of the base substrate to encapsulate the first optical sensor and the interlayer connects, wherein the interlayer connects pass through the first encapsulant layer;
providing an interposer;
mounting the second optical sensor on a front surface of the interposer, with its light receiving surface and the second light-pervious encapsulant mold facing away from the interposer;
forming a second encapsulant layer on the front surface of the interposer to encapsulate the second optical sensor; and
attaching the interposer onto the first encapsulant layer to electrically couple the interposer with the base substrate through the interlayer connects.

16. The method of claim 15, wherein forming a window through the base substrate comprises:
attaching a back surface of the base substrate onto a carrier; and
etching the base substrate to form the window.

17. The method of claim 15, wherein the first optical sensor comprises a set of conductive patterns besides its light receiving surface, and the set of conductive patterns are electrically coupled to the base substrate via a set of solder bumps between the first optical sensor and the base substrate.

18. The method of claim 15, wherein the first light-pervious encapsulant mold has a front surface that is substantially flush with a back surface of the base substrate.

19. The method of claim 15, wherein the second optical sensor comprises a set of conductive patterns besides its light receiving surface, and the method further comprises:
forming a set of bonding wires on the front surface of the interposer to electrically couple the set of conductive patterns of the second optical sensor with the interposer.
